(19) United States
(12) Patent Application Publication
(10) Pub. No.: US 2025/0267974 A1
(43) Pub. Date: Aug. 21, 2025

(54) SYSTEMS AND METHODS FOR EXPOSED PIXEL ARRAY CHIP SCALE PACKAGING

(71) Applicant: Meta Platforms Technologies, LLC, Menlo Park, CA (US)

(72) Inventor: Rajendra D Pendse, Fremont, CA (US)

(21) Appl. No.: 19/053,352

(22) Filed: Feb. 13, 2025

Related U.S. Application Data
(60) Provisional application No. 63/554,741, filed on Feb. 16, 2024.

(51) Int. Cl. H10F 39/00; H01L 21/78; H01L 23/00

(52) U.S. Cl. CPC H10F 39/811; H01L 24/11; H01L 24/13; H01L 21/78; H01L 2224/11002; H01L 2224/117; H01L 2224/13008

(57) ABSTRACT

The disclosed method may $include applying adhesive and a release layer to a temporary carrier. The method may additionally include bonding a sensor wafer to the temporary carrier face down. The method may also include forming one or more package features at least one of in or on the sensor wafer bonded to the temporary carrier. Various other methods, systems, and computer-readable media are also disclosed.

### CROSS REFERENCE TO RELATED APPLICATIONS

This application claims the benefit of U.S. Provisional Application No. 63/554,741, filed Feb. 16, 2024, the disclosure of which is incorporated, in its entirety, by this reference.

### BRIEF DESCRIPTION OF DRAWINGS

FIG. 1 is a flow diagram of exemplary methods for exposed pixel array chip scale packaging.

FIG. 2 provides block diagrams illustrating various image sensor packages formed at various stages of one or more of the methods of FIG. 1.

FIG. 3 is a flow diagram of exemplary methods implementing the method of FIG. 1.

FIG. 4 provides block diagrams illustrating various image sensor packages formed at various stages of one or more of the methods of FIG. 3.

FIG. 5 is a flow diagram of exemplary methods implementing the method of FIG. 1.

FIG. 6 provides block diagrams illustrating various image sensor packages formed at various stages of one or more of the methods of FIG. 5.

FIG. 7 is a block diagram illustrating an image sensor package.

FIG. 8 is an illustration of exemplary augmented-reality glasses that may be used in connection with embodiments of this disclosure.

FIG. 9 is an illustration of an exemplary virtual-reality headset that may be used in connection with embodiments of this disclosure.

### DETAILED DESCRIPTION OF EXEMPLARY EMBODIMENTS

An option for chip scale packaging (CSP) of image sensors may include packaging a sensor chip with its pixel array covered by a glass cover. This glass cover may be attached with a “dam” of adhesive material (e.g., applied to the perimeter region) to protect the pixel array from mechanical damage and particulate contamination during processing (e.g., through silicon via (TSV) formation, redistribution layer (RDL) formation, other processing, etc.) In an example, a combination of such a glass cover and dam may consume approximately 0.4-0.5 mm of total package thickness (e.g., approximately 0.75 mm).

The present disclosure is generally directed to systems and methods for exposed pixel array chip scale packaging. For example, the disclosed structure and process eliminate the glass cover from a CSP package for image sensors that include a sensor chip and pixel array. Rather than attaching a glass cover to a “dam” of adhesive material applied to a perimeter region, the cover and dam are eliminated, thus eliminating 0.4-0.5 mm out of a total package thickness of approximately 0.75 mm. This elimination may be accomplished by utilizing a process flow and materials that obviate the glass cover while maintaining the physical integrity of the pixel array during processing.

An example method for chip scale packaging of an image sensor may include applying adhesive and a release layer to a temporary carrier. The method may additionally include bonding a sensor wafer to the temporary carrier face down. The method may also include performing package feature formation (e.g., TSV formation, RDL formation, ball grid array (BGA) processing, etc.). In some implementations, functional testing (e.g., optoelectronic testing of one or more pixel arrays of one or more image sensors of the sensor wafer) may also be performed while the sensor wafer remains attached to the temporary carrier. Any or combinations of these procedures may be performed while the sensor wafer remains attached to the temporary carrier. The method may further include removing the sensor wafer from the temporary carrier (e.g., using any or combinations of heat, laser, mechanical force, etc.). Such removal may be performed following completion of the processes described above (e.g., package feature formation, functional testing, combinations thereof, etc.). Finally, the sensor wafer may be singulated, packed, and shipped.

An example image sensor package may include a sensor chip and pixel array that is exposed (e.g., to air) rather than being covered by glass. The sensor chip may be connected to a BGA by RDL (e.g., two or three metal layers) and have TSVs formed therein. The example image sensor package may have a package height of approximately 0.35 mm (e.g., less than 0.5 mm, less than 0.4 mm, in a range of 0.3 mm to 0.5 mm, in a range of 0.3 mm to 0.4 mm, etc.). In addition to reduced thickness, the example image sensor package may achieve better optical response due to the absence of an intervening glass layer and consequent elimination of light loss due to absorption by glass.

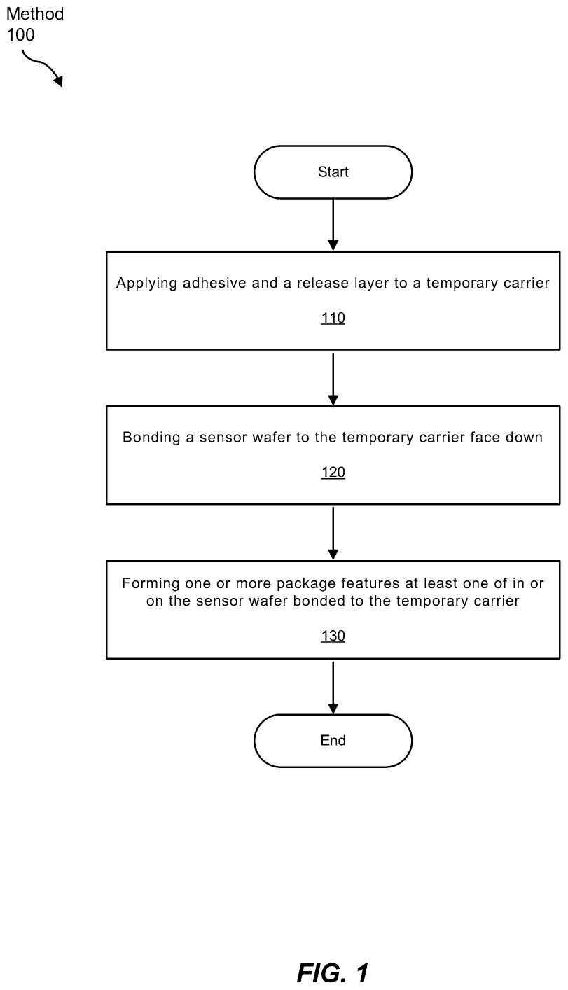

FIG. 1 illustrates methods 100 for exposed pixel array chip scale packaging. Method 100 may be carried out by humans and/or machines (e.g., workstations, chemical chambers, etc.) in various environments (e.g., clean rooms, etc.). Semiconductor device packages may be structured according to various packaging processes, such as substrate-level packaging processes or wafer-level packaging processes. For example, substrate-level packaging processes may employ a substrate to facilitate the assembly and connection of components on a base material. The substrate may ensure mechanical support, electrical pathways, and heat dissipation for integrated circuits (ICs) and electronic devices. Materials like silicon, ceramics, laminate structures, and organic compounds may be used based on specific needs.

Wafer-level packaging is a process in integrated circuit manufacturing in which packaging components may be attached to an integrated circuit (IC) before the wafer—on which the IC is fabricated—is diced. For example, the top and bottom layers of the packaging and the solder bumps may be attached to the integrated circuits while they are still in the wafer. This process differs from a process like substrate level packaging in which the wafer may be sliced into individual circuits (e.g., dice) before the packaging components are attached.

As shown in FIG. 1 at step 110, method 100 may include applying a layer. For example, method 100 may, at step 110, include applying an adhesive and release layer to a temporary carrier.

The term “adhesive,” as used herein, may generally refer to any substance that is capable of holding materials together by surface attachment that resists separation. For example, and without limitation, adhesives may include thermoplastic, crosslinking epoxy, silicone, and/or polyimide adhesives. Adhesives may correspond to liquids, pastes, and/or films. Some adhesives may be optically transparent (e.g., to wavelengths in a spectrum visible to humans).

The term “release layer,” as used herein, may generally refer to a material that allows separation of layers from a substrate. For example, and without limitation, release layers may include silicon, boron, nitride, photoresist, hydrocarbon polymer, aluminum arsenide, silicon dioxide, indium gallium arsenide, indium aluminum arsenide, or other materials. Release layers may be sacrificial and releasable by application of laser, mechanical force, and/or chemical exposure. Some release layers may be optically transparent (e.g., to wavelengths in a spectrum visible to humans).

The term “temporary carrier,” as used herein, may generally refer to a rigid platform that temporarily bonds a device wafer for processing. For example, and without limitation, a temporary carrier may be made of silicon and/or glass. Special adhesive (e.g., bonding materials) may be used to temporarily attach a semiconductor wafer to a glass carrier, permitting detachment when needed by application of laser, mechanical force, or chemical exposure. Some temporary carriers may be optically transparent (e.g., to wavelengths in a spectrum visible to humans).

As shown in FIG. 1 at step 120, method 100 may include bonding a wafer. For example, method 100 may, at step 120, include bonding a sensor wafer to the temporary carrier face down.

The term “bonding,” as used herein, may generally refer to a process of attaching a wafer to a carrier using an adhesive. For example, and without limitation, bonding may refer to a process that attaches a wafer to a carrier using an adhesive (e.g., thermoplastic, crosslinking, etc.). In this context, thermoplastic may be cleaned with solvents and crosslinking adhesives may be mechanically peeled off.

The term “sensor wafer,” as used herein, may generally refer to a wafer that includes two or more sensor structures. For example, and without limitation, a sensor wafer may include imaging devices having pixel arrays on a top surface of the wafer. In this context, the sensor wafer may be a semiconductor wafer corresponding to a thin slice of semiconductor material used to make integrated circuits and other electronic devices.

The term “face down,” as used herein, may generally refer to an orientation of a chip or wafer in which a face of the chip or wafer, as opposed to a backside of the chip or wafer, is in contact with an underlying substrate, such as a carrier. For example, and without limitation, face down may refer to an orientation of a sensor wafer that includes imaging devices having pixel arrays on faces thereof. In this context, the face down orientation of the wafer may result in the pixel arrays being bonded to the temporary carrier by the adhesive and release layer.

As shown in FIG. 1 at step 130, method 100 may include forming package features. For example, method 100 may, at step 130, include forming one or more package features at least one of in or on the sensor wafer bonded to the temporary carrier.

The term “package features,” as used herein, may generally refer to structures that provide electrical connection of a semiconductor device to another device (e.g., a printed circuit board, a camera module substrate, etc.). For example, and without limitation, package features may include through silicon vias formed in the sensor wafer, a ball grid array, and/or one or more redistribution layers. In this context, the one or more redistribution layers (e.g., two or three metal layers) may connect the ball grid array to the sensor chip (e.g., by the through silicon vias). In this context, method 100 may, at step 130, may include forming the one or more package features by through silicon via formation, redistribution layer formation, and/or ball grid array processing.

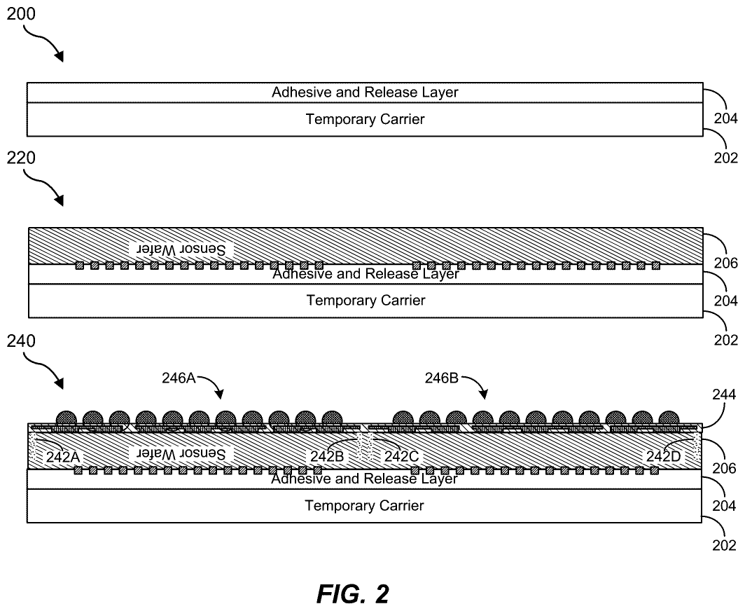

FIG. 2 illustrates various image sensor packages 200, 220, and 240 formed at various stages of one or more of the methods 100 of FIG. 1. For example, package 200 may include a temporary carrier 202 having applied thereto an adhesive and release layer 204. Package 200 may result from performance of step 110 of FIG. 1 in which the adhesive and release layer 204 may be applied to the temporary carrier 202 as detailed above.

As shown in FIG. 2, package 220 may include a sensor wafer 206 bonded face down to the temporary carrier 202 by the adhesive and release layer 204. Package 220 may result from performance of step 120 of FIG. 1 in which the sensor wafer 206 may be bonded face down to the temporary carrier 202.

As shown in FIG. 2, package 240 may include one or more package features, such as through silicon vias 242A, 242B, 242C, and 242D, one or more redistribution layers 244, and/or one or more ball grid arrays 246A and 246B. Package 240 may result from performance of step 130 of FIG. 1 in which the one or more package features may be formed at least one of in or on the sensor wafer 206 bonded to the temporary carrier 202 by the adhesive and release layer 204.

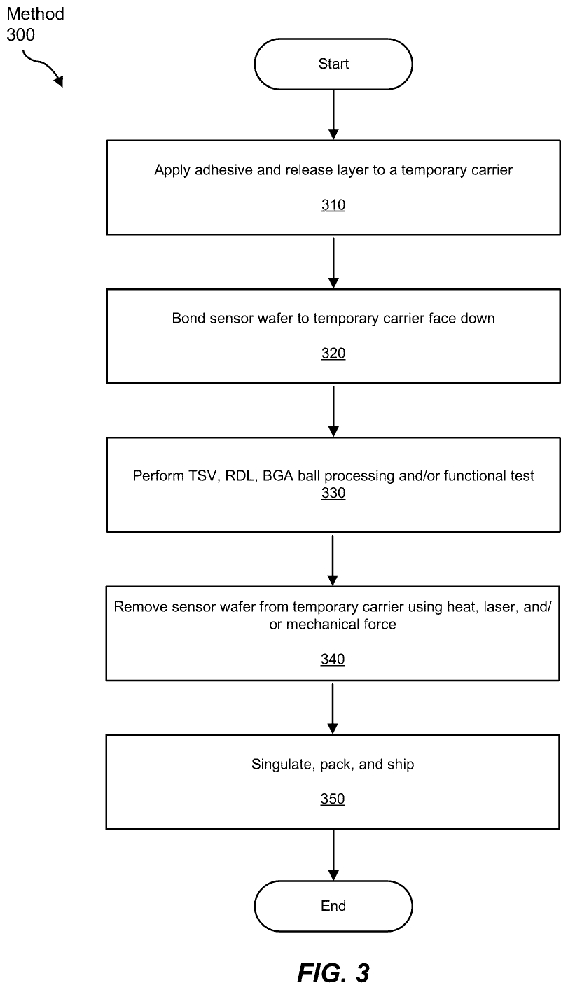

FIG. 3 illustrates exemplary methods 300 implementing the method 100 of FIG. 1. For example, steps 310, 320, and 330 of method 300 may implement steps 110, 120, and 130 of FIG. 1, respectively. In this context, step 310 of method 300 may implement step 110 of method 100 of FIG. 1 by applying an adhesive and release layer to a temporary carrier, which may result in package 200 of FIG. 2. Step 320 of method 300 may implement step 120 of method 100 of FIG. 1 by bonding a sensor wafer face down to a temporary carrier, which may result in package 220 of FIG. 2. Step 330 of method 300 may implement step 130 of method 100 of FIG. 1 by forming one or more package features in and/or on the sensor wafer bonded to the temporary carrier by the adhesive and release layer, which may result in package 240 of FIG. 2. Additionally, step 330 of method 300 may include performing functional testing of the sensor wafer bonded to the temporary carrier. To facilitate this functional testing (e.g., optoelectronic testing of one or more pixel arrays of one or more image sensors of the sensor wafer), an optically transparent adhesive and release layer may be applied in step 110 of FIG. 1 and step 310 of FIG. 3. Moreover, the adhesive and release layer 204 and the temporary carrier 202 of FIG. 2 may be optically transparent to permit visible light to be received by a pixel array of the sensor wafer 206.

The term “optoelectronic testing,” as used herein, may generally refer to evaluation of performance of optoelectronic devices and systems. For example, and without limitation, optoelectronic testing methods may include evaluating photoelectronic response (e.g., by measuring how a device responds to light signals, such as photocurrent and photovoltage), reverse breakdown (e.g., by injecting a small reverse current into the device while measuring the voltage), active alignment (e.g., by aligning optics and a sensor in a camera system), and/or performance (e.g., by ensuring that all features of a device meet its requirements). In these contexts, optoelectronic testing equipment may include multimeters (e.g., to test optocouplers and opto-isolators), optoelectronic testing platforms (e.g., to measure performance of CCD/CMOS sensors and cameras), and/or probe stations (e.g., to test light-emitting diodes (LEDs), photodiodes, and other devices).

The term “pixel array,” as used herein, may generally refer to an array of photosensitive pixels of an image sensor. For example, and without limitation, individual pixels of a pixel array may include various electronic component structures such as a photodiode and capacitor structure (e.g., a photodiode array), a switching transistor and a phototransistor (e.g., active pixel array), combinations thereof, etc. In this context, additional structural elements of pixels of a pixel array may include microlenses, color filters, etc.

As shown in FIG. 3, method 300, at step 340, may additionally include removing the sensor wafer from the temporary carrier. For example, method 300 may, at step 340, remove the sensor wafer from the temporary carrier using heat, laser, and/or mechanical force. Additionally, at step 350, method 300 may include singulating the sensor wafer. In this context, removing the sensor wafer at step 340 and singulating it at step 350 may produce an image sensor package. The produced image sensor package may include a sensor chip having an exposed pixel array. Alternatively or additionally, the produced image sensor package may also have a package height no greater than 0.5 mm. For example, the produced image sensor package may have a package height of approximately 0.35 mm (e.g., less than 0.5 mm, less than 0.4 mm, in a range of 0.3 mm to 0.5 mm, in a range of 0.3 mm to 0.4 mm, etc.). Further, step 350 may include packing and shipping the produced image sensor package.

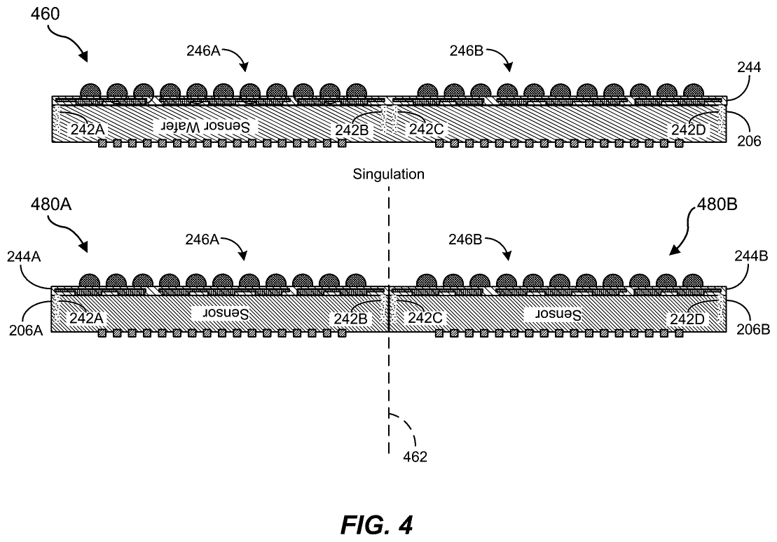

FIG. 4 illustrates various image sensor packages 460, 480A, and 480B formed at various stages of the method 300 of FIG. 3. For example, package 460 may include sensor wafer 206 and one or more package features, such as through silicon vias 242A, 242B, 242C, and 242D, one or more redistribution layers 244, and/or one or more ball grid arrays 246A and 246B. Package 460 may result from performance of step 340 of FIG. 3 in which the sensor wafer may be removed from a temporary carrier, such as temporary carrier 202 of package 240 of FIG. 2.

As shown in FIG. 4, packages 480A and 480B may result from singulation 462 (e.g. dicing apart) of package 460 in accordance with step 350 of method 300 of FIG. 3. Package 480A, for example, may correspond to an image sensor package that includes an image sensor 206A and one or more package features, such as through silicon vias 242A and 242B, one or more redistribution layers 244A, and/or a ball grid array 246A. Likewise, package 480B may correspond to an image sensor package that includes an image sensor 206B and one or more package features, such as through silicon vias 242C and 242D, one or more redistribution layers 244B, and/or a ball grid array 246B.

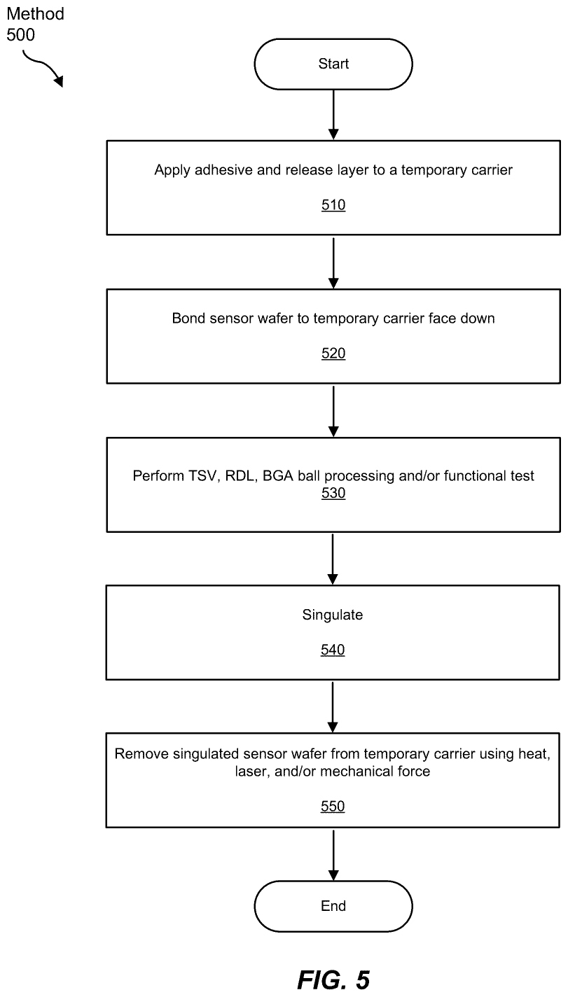

FIG. 5 illustrates exemplary methods implementing the method of FIG. 1. For example, steps 510, 520, and 530 of method 500 may implement steps 110, 120, and 130 of FIG. 1, respectively. In this context, step 510 of method 500 may implement step 110 of method 100 of FIG. 1 by applying an adhesive and release layer to a temporary carrier, which may result in package 200 of FIG. 2. Step 520 of method 500 may implement step 120 of method 100 of FIG. 1 by bonding a sensor wafer face down to a temporary carrier, which may result in package 220 of FIG. 2. Step 530 of method 500 may implement step 130 of method 100 of FIG. 1 by forming one or more package features in and/or on the sensor wafer bonded to the temporary carrier by the adhesive and release layer, which may result in package 240 of FIG. 2. Additionally, step 530 of method 500 may include performing functional testing of the sensor wafer bonded to the temporary carrier. To facilitate this functional testing (e.g., optoelectronic testing of one or more pixel arrays of one or more image sensors of the sensor wafer), an optically transparent adhesive and release layer may be applied in step 110 of FIG. 1 and step 510 of FIG. 5. Moreover, the adhesive and release layer 204 and the temporary carrier 202 of FIG. 2 may be optically transparent to permit visible light to be received by a pixel array of the sensor wafer 206 while the sensor wafer remains attached to the temporary carrier.

As shown in FIG. 5, method 500, at step 540, may additionally include singulating the sensor wafer. Additionally, at step 550, method 500 may include removing the sensor wafer from the temporary carrier. For example, method 500 may, at step 550, remove the sensor wafer from the temporary carrier using heat, laser, and/or mechanical force. In this context, singulating the sensor wafer at step 540 and removing it from the temporary carrier at step 550 may produce an image sensor package. The produced image sensor package may include a sensor chip having an exposed pixel array. Alternatively or additionally, the produced image sensor package may also have a package height no greater than 0.5 mm. For example, the produced image sensor package may have a package height of approximately 0.35 mm (e.g., less than 0.5 mm, less than 0.4 mm, in a range of 0.3 mm to 0.5 mm, in a range of 0.3 mm to 0.4 mm, etc.). Further, step 550 may include packing and shipping the produced image sensor package.

As shown in FIG. 5, step 540 and/or step 550 may include packing and shipping the produced image sensor package. For example, step 540 may include packing and shipping the produced image sensor package that is still attached to a singulated temporary carrier portion, followed by removal of the image sensor package, at step 550, from the temporary carrier portion by a recipient thereof. Alternatively, step 550 may include packing and shipping the produced image sensor package after it is removed from the singulated temporary carrier portion. In another example, singulating the sensor wafer at step 540 may singulate the sensor wafer without also singulating the temporary carrier, allowing removal of the image sensor package from the temporary carrier at step 550. This image sensor package may then be packed and shipped in step 550.

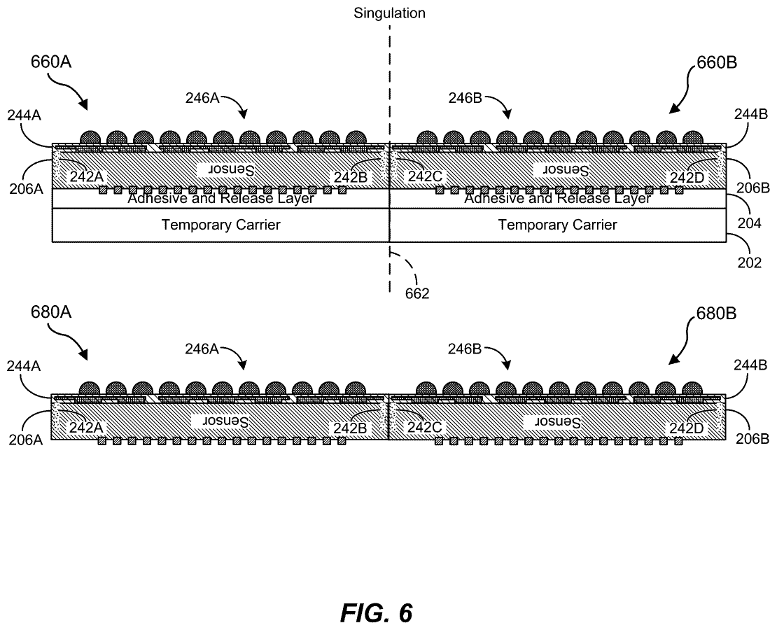

FIG. 6 illustrates various image sensor packages 660A, 660B, 680A, and 680B formed at various stages of one or more of the methods 500 of FIG. 5. For example, packages 660A and 660B may result from singulation 662 (e.g. dicing apart) of package 240 of FIG. 2 in accordance with step 540 of method 500 of FIG. 5. Package 660A, for example, may correspond to an image sensor package that includes an image sensor 206A and one or more package features, such as through silicon vias 242A and 242B, one or more redistribution layers 244A, and/or a ball grid array 246A. Likewise, package 660B may correspond to an image sensor package that includes an image sensor 206B and one or more package features, such as through silicon vias 242C and 242D, one or more redistribution layers 244B, and/or a ball grid array 246B. Additionally, packages 660A and 660B may be attached to temporary carrier 202 (e.g., or portions thereof) by adhesive and release layer 204 of FIG. 2.

As shown in FIG. 6, packages 680A and 680B may result from performance of step 550 of FIG. 5 in which the sensor wafer may be removed from the temporary carrier, such as temporary carrier 202 of package 240 of FIG. 2 or portions thereof. Package 680A, for example, may correspond to an image sensor package that includes an image sensor 206A and one or more package features, such as through silicon vias 242A and 242B, one or more redistribution layers 244A, and/or a ball grid array 246A. Likewise, package 680B may correspond to an image sensor package that includes an image sensor 206B and one or more package features, such as through silicon vias 242C and 242D, one or more redistribution layers 244B, and/or a ball grid array 246B.

As shown in FIGS. 3-6, packages 480A, 480B, 680A, or 680B may be rendered free of any remnants of adhesive and release layer 204 (e.g., in an area of the pixel array). Removal of such remnants may be accomplished by any suitable method of cleaning a pixel array of an image sensor. For example, and without limitation, the pixel array may be cleaned by etching (e.g., chemical, wet, dry, etc.).

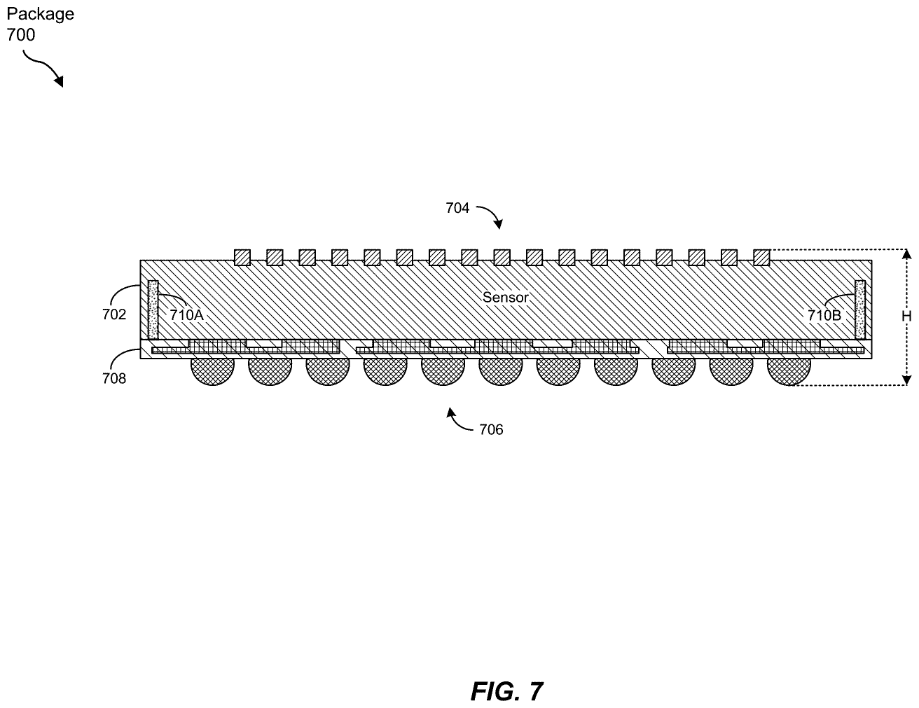

FIG. 7 illustrates an image sensor package 700 that may correspond to any of image sensor packages 480A, 480B, 680A, or 680B of FIG. 4 and FIG. 6. Package 700, for example, may include a sensor chip 702 having an exposed pixel array 704 and one or more package features formed in and/or on the sensor chip 702. For example, and without limitation, the one or more package features may include a ball grid array 706, one or more redistribution layers 708 (e.g., connecting the ball grid array 704 to the sensor chip 702), and/or one or more through silicon vias 710A and 710B formed in the sensor chip 702. Image sensor package 700 may have a package height H (e.g., measured from a bottommost surface of the one or more package features (e.g., ball grid array 706) to a topmost surface of the exposed pixel array 704 (e.g., a microlens of the pixel array 704)) of approximately 0.35 mm (e.g., less than 0.5 mm, less than 0.4 mm, in a range of 0.3 mm to 0.5 mm, in a range of 0.3 mm to 0.4 mm, etc.). In addition to reduced thickness, image sensor package 700 may achieve better optical response due to the absence of an intervening glass layer and consequent elimination of light loss due to absorption by glass.

As set forth above, thermally stable but mechanically compliant adhesive materials in conjunction with release layers may be used to bond the sensor wafer face down to a temporary process carrier during processing followed by the removal of the sensor wafer from the carrier at the end of the process. The resulting CSP package may provide reduced thickness (e.g., reduction from approximately 0.75 mm to approximately 0.35 mm) and better optical response due to the absence of the intervening glass layer and consequent elimination of light loss due to absorption by glass.

### Example Embodiments

Example 1: A method may include applying adhesive and a release layer to a temporary carrier, bonding a sensor wafer to the temporary carrier face down; and forming one or more package features at least one of in or on the sensor wafer bonded to the temporary carrier.

Example 2: The method of example 1, wherein forming the one or more package features includes at least one of through silicon via formation, redistribution layer formation, or ball grid array processing.

Example 3: The method of any of examples 1 or 2, further including performing functional testing of the sensor wafer bonded to the temporary carrier.

Example 4: The method of any of examples 1-3, wherein the adhesive is optically transparent to facilitate optoelectronic testing of one or more pixel arrays of one or more image sensors of the sensor wafer while the sensor wafer remains attached to the temporary carrier.

Example 5: The method of any of examples 1-4, further including removing the sensor wafer from the temporary carrier.

Example 6: The method of any of examples 1-5, wherein removing the sensor wafer includes using at least one of heat, laser, or mechanical force.

Example 7: The method of any of examples 1-6, further including singulating the sensor wafer.

Example 8: The method of any of examples 1-7, wherein removing the temporary carrier and singulating the sensor wafer produces an image sensor package.

Example 9: The method of any of examples 1-8, wherein the image sensor package includes a sensor chip having an exposed pixel array.

Example 10: The method of any of examples 1-9, wherein the image sensor package has a package height no greater than 0.5 mm.

Example 11: An image sensor package may include a sensor chip having an exposed pixel array and one or more package features formed at least one of in or on the sensor chip.

Example 12: The image sensor package of example 11, wherein the one or more package features include a ball grid array.

Example 13: The image sensor package of any of examples 11 or 12, wherein the one or more package features include one or more redistribution layers connecting the ball grid array to the sensor chip.

Example 14: The image sensor package of any of examples 11-13, wherein the one or more package features include one or more redistribution layers.

Example 15: The image sensor package of any of examples 11-14, wherein the one or more package features include one or more through silicon vias formed in the sensor chip.

Example 16: The image sensor package of any of examples 11-15, wherein the image sensor package has a package height no greater than 0.5 mm.

Example 17: The image sensor package of any of examples 11-16, wherein the image sensor package has a package height no greater than 0.4 mm.

Example 18: The image sensor package of any of examples 11-17, wherein the image sensor package has a package height in a range of 0.3 mm to 0.5 mm.

Example 19: A head mounted display may include one or more display devices and at least one image sensor package that includes a sensor chip having an exposed pixel array and one or more package features formed at least one of in or on the sensor chip.

Example 20: The head mounted display of example 19, wherein the at least one image sensor package has a package height no greater than 0.5 mm.

Embodiments of the present disclosure may include or be implemented in conjunction with various types of artificial-reality systems. Artificial reality is a form of reality that has been adjusted in some manner before presentation to a user, which may include, for example, a virtual reality, an augmented reality, a mixed reality, a hybrid reality, or some combination and/or derivative thereof. Artificial-reality content may include completely computer-generated content or computer-generated content combined with captured (e.g., real-world) content. The artificial-reality content may include video, audio, haptic feedback, or some combination thereof, any of which may be presented in a single channel or in multiple channels (such as stereo video that produces a three-dimensional (3D) effect to the viewer). Additionally, in some embodiments, artificial reality may also be associated with applications, products, accessories, services, or some combination thereof, that are used to, for example, create content in an artificial reality and/or are otherwise used in (e.g., to perform activities in) an artificial reality.

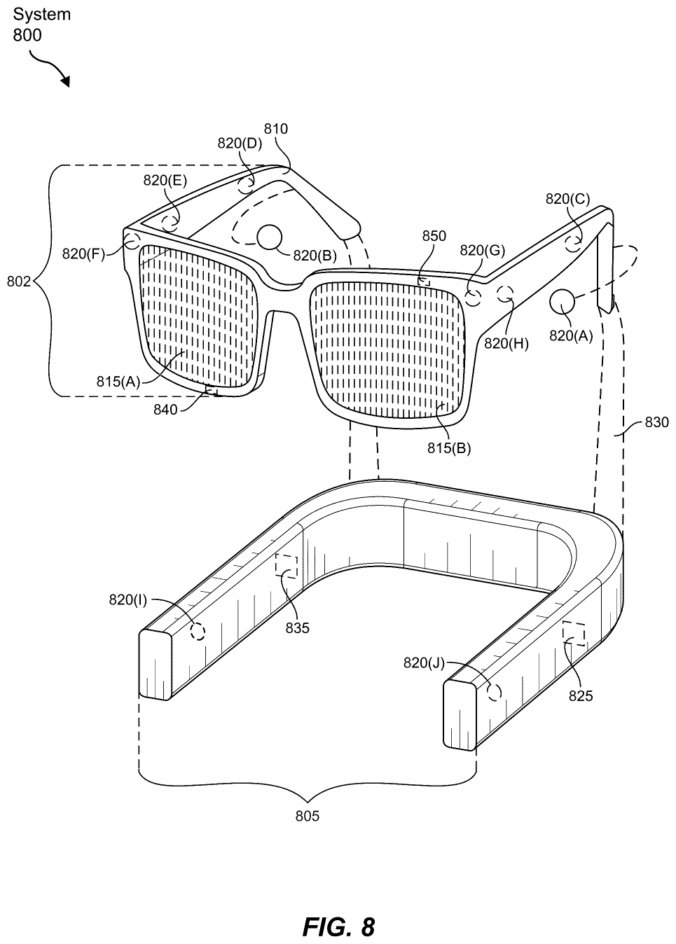

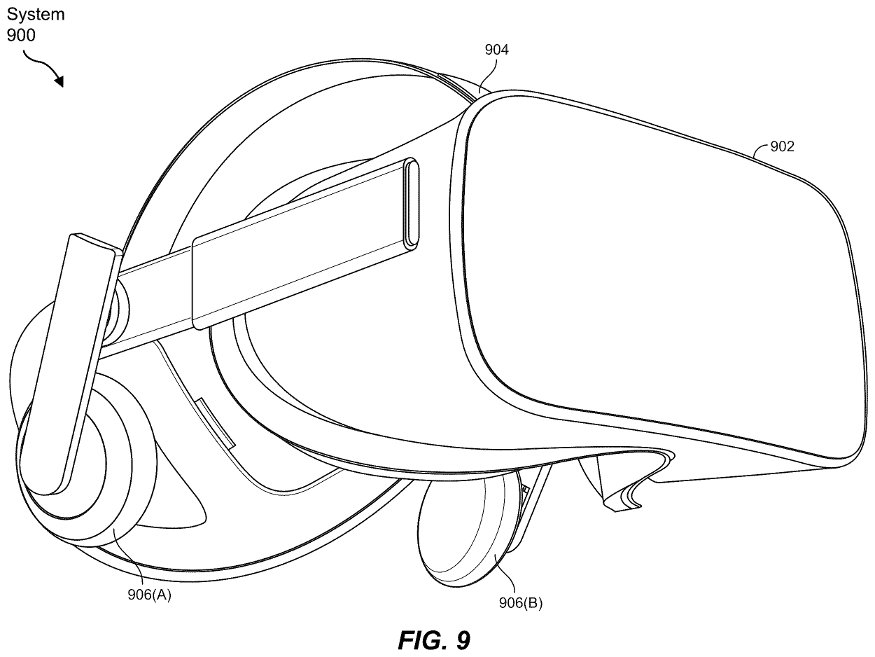

Artificial-reality systems may be implemented in a variety of different form factors and configurations. Some artificial-reality-systems may be designed to work without near-eye displays (NEDs). Other artificial-reality systems may include an NED that also provides visibility into the real world (such as, e.g., augmented-reality system 800 in FIG. 8) or that visually immerses a user in an artificial reality (such as, e.g., virtual-reality system 900 in FIG. 9). While some artificial-reality devices may be self-contained systems, other artificial-reality devices may communicate and/or coordinate with external devices to provide an artificial-reality experience to a user. Examples of such external devices include handheld controllers, mobile devices, desktop computers, devices worn by a user, devices worn by one or more other users, and/or any other suitable external system.

Turning to FIG. 8, augmented-reality system 800 may include an eyewear device 802 with a frame 810 configured to hold a left display device 815(A) and a right display device 815(B) in front of a user's eyes. Display devices 815(A) and 815(B) may act together or independently to present an image or series of images to a user. While augmented-reality system 800 includes two displays, embodiments of this disclosure may be implemented in augmented-reality systems with a single NED or more than two NEDs.

In some embodiments, augmented-reality system 800 may include one or more sensors, such as sensor 840. Sensor 840 may generate measurement signals in response to motion of augmented-reality system 800 and may be located on substantially any portion of frame 810. Sensor 840 may represent one or more of a variety of different sensing mechanisms, such as a position sensor, an inertial measurement unit (IMU), a depth camera assembly, a structured light emitter and/or detector, or any combination thereof. In some embodiments, augmented-reality system 800 may or may not include sensor 840 or may include more than one sensor. In embodiments in which sensor 840 includes an IMU, the IMU may generate calibration data based on measurement signals from sensor 840. Examples of sensor 840 may include, without limitation, accelerometers, gyroscopes, magnetometers, other suitable types of sensors that detect motion, sensors used for error correction of the IMU, or some combination thereof.

In some examples, augmented-reality system 800 may also include a microphone array with a plurality of acoustic transducers 820(A)-820(J), referred to collectively as acoustic transducers 820. Acoustic transducers 820 may represent transducers that detect air pressure variations induced by sound waves. Each acoustic transducer 820 may be configured to detect sound and convert the detected sound into an electronic format (e.g., an analog or digital format). The microphone array in FIG. 8 may include, for example, ten acoustic transducers: 820(A) and 820(B), which may be designed to be placed inside a corresponding ear of the user, acoustic transducers 820(C), 820(D), 820(E), 820(F), 820(G), and 820(H), which may be positioned at various locations on frame 810, and/or acoustic transducers 820(I) and 820(J), which may be positioned on a corresponding neckband 805.

In some embodiments, one or more of acoustic transducers 820(A)-(J) may be used as output transducers (e.g., speakers). For example, acoustic transducers 820(A) and/or 820(B) may be earbuds or any other suitable type of headphone or speaker.

The configuration of acoustic transducers 820 of the microphone array may vary. While augmented-reality system 800 is shown in FIG. 8 as having ten acoustic transducers 820, the number of acoustic transducers 820 may be greater or less than ten. In some embodiments, using higher numbers of acoustic transducers 820 may increase the amount of audio information collected and/or the sensitivity and accuracy of the audio information. In contrast, using a lower number of acoustic transducers 820 may decrease the computing power required by an associated controller 850 to process the collected audio information. In addition, the position of each acoustic transducer 820 of the microphone array may vary. For example, the position of an acoustic transducer 820 may include a defined position on the user, a defined coordinate on frame 810, an orientation associated with each acoustic transducer 820, or some combination thereof.

Acoustic transducers 820(A) and 820(B) may be positioned on different parts of the user's ear, such as behind the pinna, behind the tragus, and/or within the auricle or fossa. Or, there may be additional acoustic transducers 820 on or surrounding the ear in addition to acoustic transducers 820 inside the ear canal. Having an acoustic transducer 820 positioned next to an ear canal of a user may enable the microphone array to collect information on how sounds arrive at the ear canal. By positioning at least two of acoustic transducers 820 on either side of a user's head (e.g., as binaural microphones), augmented-reality system 800 may simulate binaural hearing and capture a 3D stereo sound field around about a user's head. In some embodiments, acoustic transducers 820(A) and 820(B) may be connected to augmented-reality system 800 via a wired connection 830, and in other embodiments acoustic transducers 820(A) and 820(B) may be connected to augmented-reality system 800 via a wireless connection (e.g., a BLUETOOTH connection). In still other embodiments, acoustic transducers 820(A) and 820(B) may not be used at all in conjunction with augmented-reality system 800.

Acoustic transducers 820 on frame 810 may be positioned in a variety of different ways, including along the length of the temples, across the bridge, above or below display devices 815(A) and 815(B), or some combination thereof. Acoustic transducers 820 may also be oriented such that the microphone array is able to detect sounds in a wide range of directions surrounding the user wearing the augmented-reality system 800. In some embodiments, an optimization process may be performed during manufacturing of augmented-reality system 800 to determine relative positioning of each acoustic transducer 820 in the microphone array.

In some examples, augmented-reality system 800 may include or be connected to an external device (e.g., a paired device), such as neckband 805. Neckband 805 generally represents any type or form of paired device. Thus, the following discussion of neckband 805 may also apply to various other paired devices, such as charging cases, smart watches, smart phones, wrist bands, other wearable devices, hand-held controllers, tablet computers, laptop computers, other external compute devices, etc.

As shown, neckband 805 may be coupled to eyewear device 802 via one or more connectors. The connectors may be wired or wireless and may include electrical and/or non-electrical (e.g., structural) components. In some cases, eyewear device 802 and neckband 805 may operate independently without any wired or wireless connection between them. While FIG. 8 illustrates the components of eyewear device 802 and neckband 805 in example locations on eyewear device 802 and neckband 805, the components may be located elsewhere and/or distributed differently on eyewear device 802 and/or neckband 805. In some embodiments, the components of eyewear device 802 and neckband 805 may be located on one or more additional peripheral devices paired with eyewear device 802, neckband 805, or some combination thereof.

Pairing external devices, such as neckband 805, with augmented-reality eyewear devices may enable the eyewear devices to achieve the form factor of a pair of glasses while still providing sufficient battery and computation power for expanded capabilities. Some or all of the battery power, computational resources, and/or additional features of augmented-reality system 800 may be provided by a paired device or shared between a paired device and an eyewear device, thus reducing the weight, heat profile, and form factor of the eyewear device overall while still retaining desired functionality. For example, neckband 805 may allow components that would otherwise be included on an eyewear device to be included in neckband 805 since users may tolerate a heavier weight load on their shoulders than they would tolerate on their heads. Neckband 805 may also have a larger surface area over which to diffuse and disperse heat to the ambient environment. Thus, neckband 805 may allow for greater battery and computation capacity than might otherwise have been possible on a stand-alone eyewear device. Since weight carried in neckband 805 may be less invasive to a user than weight carried in eyewear device 802, a user may tolerate wearing a lighter eyewear device and carrying or wearing the paired device for greater lengths of time than a user would tolerate wearing a heavy standalone eyewear device, thereby enabling users to more fully incorporate artificial-reality environments into their day-to-day activities.

Neckband 805 may be communicatively coupled with eyewear device 802 and/or to other devices. These other devices may provide certain functions (e.g., tracking, localizing, depth mapping, processing, storage, etc.) to augmented-reality system 800. In the embodiment of FIG. 8, neckband 805 may include two acoustic transducers (e.g., 820(I) and 820(J)) that are part of the microphone array (or potentially form their own microphone subarray). Neckband 805 may also include a controller 825 and a power source 835.

Acoustic transducers 820(I) and 820(J) of neckband 805 may be configured to detect sound and convert the detected sound into an electronic format (analog or digital). In the embodiment of FIG. 8, acoustic transducers 820(I) and 820(J) may be positioned on neckband 805, thereby increasing the distance between the neckband acoustic transducers 820(I) and 820(J) and other acoustic transducers 820 positioned on eyewear device 802. In some cases, increasing the distance between acoustic transducers 820 of the microphone array may improve the accuracy of beamforming performed via the microphone array. For example, if a sound is detected by acoustic transducers 820(C) and 820(D) and the distance between acoustic transducers 820(C) and 820(D) is greater than, e.g., the distance between acoustic transducers 820(D) and 820(E), the determined source location of the detected sound may be more accurate than if the sound had been detected by acoustic transducers 820(D) and 820(E).

Controller 825 of neckband 805 may process information generated by the sensors on neckband 805 and/or augmented-reality system 800. For example, controller 825 may process information from the microphone array that describes sounds detected by the microphone array. For each detected sound, controller 825 may perform a direction-of-arrival (DOA) estimation to estimate a direction from which the detected sound arrived at the microphone array. As the microphone array detects sounds, controller 825 may populate an audio data set with the information. In embodiments in which augmented-reality system 800 includes an inertial measurement unit, controller 825 may compute all inertial and spatial calculations from the IMU located on eyewear device 802. A connector may convey information between augmented-reality system 800 and neckband 805 and between augmented-reality system 800 and controller 825. The information may be in the form of optical data, electrical data, wireless data, or any other transmittable data form. Moving the processing of information generated by augmented-reality system 800 to neckband 805 may reduce weight and heat in eyewear device 802, making it more comfortable to the user.

Power source 835 in neckband 805 may provide power to eyewear device 802 and/or to neckband 805. Power source 835 may include, without limitation, lithium-ion batteries, lithium-polymer batteries, primary lithium batteries, alkaline batteries, or any other form of power storage. In some cases, power source 835 may be a wired power source. Including power source 835 on neckband 805 instead of on eyewear device 802 may help better distribute the weight and heat generated by power source 835.

As noted, some artificial-reality systems may, instead of blending an artificial reality with actual reality, substantially replace one or more of a user's sensory perceptions of the real world with a virtual experience. One example of this type of system is a head-worn display system, such as virtual-reality system 900 in FIG. 9, that mostly or completely covers a user's field of view. Virtual-reality system 900 may include a front rigid body 902 and a band 904 shaped to fit around a user's head. Virtual-reality system 900 may also include output audio transducers 906(A) and 906(B). Furthermore, while not shown in FIG. 9, front rigid body 902 may include one or more electronic elements, including one or more electronic displays, one or more inertial measurement units (IMUs), one or more tracking emitters or detectors, and/or any other suitable device or system for creating an artificial-reality experience.

Artificial-reality systems may include a variety of types of visual feedback mechanisms. For example, display devices in augmented-reality system 800 and/or virtual-reality system 900 may include one or more liquid crystal displays (LCDs), light emitting diode (LED) displays, microLED displays, organic LED (OLED) displays, digital light project (DLP) micro-displays, liquid crystal on silicon (LCoS) micro-displays, and/or any other suitable type of display screen. These artificial-reality systems may include a single display screen for both eyes or may provide a display screen for each eye, which may allow for additional flexibility for varifocal adjustments or for correcting a user's refractive error. Some of these artificial-reality systems may also include optical subsystems having one or more lenses (e.g., concave or convex lenses, Fresnel lenses, adjustable liquid lenses, etc.) through which a user may view a display screen. These optical subsystems may serve a variety of purposes, including to collimate (e.g., make an object appear at a greater distance than its physical distance), to magnify (e.g., make an object appear larger than its actual size), and/or to relay (to, e.g., the viewer's eyes) light. These optical subsystems may be used in a non-pupil-forming architecture (such as a single lens configuration that directly collimates light but results in so-called pincushion distortion) and/or a pupil-forming architecture (such as a multi-lens configuration that produces so-called barrel distortion to nullify pincushion distortion).

In addition to or instead of using display screens, some of the artificial-reality systems described herein may include one or more projection systems. For example, display devices in augmented-reality system 800 and/or virtual-reality system 900 may include micro-LED projectors that project light (using, e.g., a waveguide) into display devices, such as clear combiner lenses that allow ambient light to pass through. The display devices may refract the projected light toward a user's pupil and may enable a user to simultaneously view both artificial-reality content and the real world. The display devices may accomplish this using any of a variety of different optical components, including waveguide components (e.g., holographic, planar, diffractive, polarized, and/or reflective waveguide elements), light-manipulation surfaces and elements (such as diffractive, reflective, and refractive elements and gratings), coupling elements, etc. Artificial-reality systems may also be configured with any other suitable type or form of image projection system, such as retinal projectors used in virtual retina displays.

The artificial-reality systems described herein may also include various types of computer vision components and subsystems. For example, augmented-reality system 800 and/or virtual-reality system 900 may include one or more optical sensors, such as two-dimensional (2D) or 3D cameras, structured light transmitters and detectors, time-of-flight depth sensors, single-beam or sweeping laser rangefinders, 3D LiDAR sensors, and/or any other suitable type or form of optical sensor. An artificial-reality system may process data from one or more of these sensors to identify a location of a user, to map the real world, to provide a user with context about real-world surroundings, and/or to perform a variety of other functions.

The artificial-reality systems described herein may also include one or more input and/or output audio transducers. Output audio transducers may include voice coil speakers, ribbon speakers, electrostatic speakers, piezoelectric speakers, bone conduction transducers, cartilage conduction transducers, tragus-vibration transducers, and/or any other suitable type or form of audio transducer. Similarly, input audio transducers may include condenser microphones, dynamic microphones, ribbon microphones, and/or any other type or form of input transducer. In some embodiments, a single transducer may be used for both audio input and audio output.

In some embodiments, the artificial-reality systems described herein may also include tactile (i.e., haptic) feedback systems, which may be incorporated into headwear, gloves, body suits, handheld controllers, environmental devices (e.g., chairs, floormats, etc.), and/or any other type of device or system. Haptic feedback systems may provide various types of cutaneous feedback, including vibration, force, traction, texture, and/or temperature. Haptic feedback systems may also provide various types of kinesthetic feedback, such as motion and compliance. Haptic feedback may be implemented using motors, piezoelectric actuators, fluidic systems, and/or a variety of other types of feedback mechanisms. Haptic feedback systems may be implemented independent of other artificial--reality devices, within other artificial-reality devices, and/or in conjunction with other artificial-reality devices.

By providing haptic sensations, audible content, and/or visual content, artificial-reality systems may create an entire virtual experience or enhance a user's real-world experience in a variety of contexts and environments. For instance, artificial-reality systems may assist or extend a user's perception, memory, or cognition within a particular environment. Some systems may enhance a user's interactions with other people in the real world or may enable more immersive interactions with other people in a virtual world. Artificial-reality systems may also be used for educational purposes (e.g., for teaching or training in schools, hospitals, government organizations, military organizations, business enterprises, etc.), entertainment purposes (e.g., for playing video games, listening to music, watching video content, etc.), and/or for accessibility purposes (e.g., as hearing aids, visual aids, etc.). The embodiments disclosed herein may enable or enhance a user's artificial--reality experience in one or more of these contexts and environments and/or in other contexts and environments.

The process parameters and sequence of the steps described and/or illustrated herein are given by way of example only and can be varied as desired. For example, while the steps illustrated and/or described herein may be shown or discussed in a particular order, these steps do not necessarily need to be performed in the order illustrated or discussed. The various exemplary methods described and/or illustrated herein may also omit one or more of the steps described or illustrated herein or include additional steps in addition to those disclosed.

The preceding description has been provided to enable others skilled in the art to best utilize various aspects of the exemplary embodiments disclosed herein. This exemplary description is not intended to be exhaustive or to be limited to any precise form disclosed. Many modifications and variations are possible without departing from the spirit and scope of the present disclosure. The embodiments disclosed herein should be considered in all respects illustrative and not restrictive. Reference should be made to any claims appended hereto and their equivalents in determining the scope of the present disclosure.

Unless otherwise noted, the terms “connected to” and “coupled to” (and their derivatives), as used in the specification and/or claims, are to be construed as permitting both direct and indirect (i.e., via other elements or components) connection. In addition, the terms “a” or “an,” as used in the specification and/or claims, are to be construed as meaning “at least one of.” Finally, for ease of use, the terms “including” and “having” (and their derivatives), as used in the specification and/or claims, are interchangeable with and have the same meaning as the word “comprising.”

What is claimed is:

1. A method comprising:
applying adhesive and a release layer to a temporary carrier;
bonding a sensor wafer to the temporary carrier face down; and
forming one or more package features at least one of in or on the sensor wafer bonded to the temporary carrier.

2. The method of claim 1, wherein forming the one or more package features includes at least one of through silicon via formation, redistribution layer formation, or ball grid array processing.

3. The method of claim 1, further comprising:
performing functional testing of the sensor wafer bonded to the temporary carrier.

4. The method of claim 3, wherein the adhesive is optically transparent to facilitate optoelectronic testing of one or more pixel arrays of one or more image sensors of the sensor wafer while the sensor wafer remains attached to the temporary carrier.

5. The method of claim 1, further comprising:
removing the sensor wafer from the temporary carrier.

6. The method of claim 5, wherein removing the sensor wafer includes using at least one of heat, laser, or mechanical force.

7. The method of claim 5, further comprising:
singulating the sensor wafer.

8. The method of claim 7, wherein removing the temporary carrier and singulating the sensor wafer produces an image sensor package.

9. The method of claim 8, wherein the image sensor package includes a sensor chip having an exposed pixel array. 10 The method of claim 8, wherein the image sensor package has a package height no greater than 0.5 mm.

11. An image sensor package comprising:
a sensor chip having an exposed pixel array; and
one or more package features formed at least one of in or on the sensor chip.

12. The image sensor package of claim 11, wherein the one or more package features include a ball grid array.

13. The image sensor package of claim 12, wherein the one or more package features include one or more redistribution layers connecting the ball grid array to the sensor chip.

14. The image sensor package of claim 11, wherein the one or more package features include one or more redistribution layers.

15. The image sensor package of claim 11, wherein the one or more package features include one or more through silicon vias formed in the sensor chip.

16. The image sensor package of claim 11, wherein the image sensor package has a package height no greater than 0.5 mm.

17. The image sensor package of claim 11, wherein the image sensor package has a package height no greater than 0.4 mm.

18. The image sensor package of claim 11, wherein the image sensor package has a package height in a range of 0.3 mm to 0.5 mm.

19. A head mounted display comprising:
one or more display devices; and
at least one image sensor package that includes:
a sensor chip having an exposed pixel array; and
one or more package features formed at least one of in or on the sensor chip.

20. The head mounted display of claim 19, wherein the at least one image sensor package has a package height no greater than 0.5 mm.
